(19) United States
(12) Patent Application Publication
(10) Pub. No.: US 2006/0172526 A1
(43) Pub. Date: Aug. 3, 2006

(54) Method for preventing edge peeling defect

(75) Inventors: Chia-Lin Hsu, Taipei City (TW); Shu-Hsien Lee, Taichung City (TW); Chien-Chien Tsai, Taichung City (TW); Hsiao-Ling Lu, Hsin-Chu (TW)

Correspondence Address: ARENT FOX PLLC, 1050 CONNECTICUT AVENUE, N.W., SUITE 400, WASHINGTON, DC, 20036, US

(73) Assignee: United Microelectronics Corp.

(21) Appl. No.: 11/331,361

(22) Filed: Jan. 13, 2006

Related U.S. Application Data
(63) Continuation-in-part of application No. 10/685,588, filed on Oct. 16, 2003.

(51) Int. Cl. H01L 21/4763

(52) U.S. Cl. 438/626

(57) ABSTRACT

A method for improving edge peeling defect is disclosed in this invention. According to this invention, a wafer can be kept from the edge peeling defect of the prior art by introducing a step for removing the weakly adhesive films and the metal structures at the wafer edge after forming a metal interconnect layer on the wafer. Thus, this invention can raise the yield of semiconductor manufacturing, and reduce the pollution chance of the chamber of the semiconductor manufacture.

This application is a continuation in part of U.S. patent application Ser. No. 10/685,588, filed Oct. 16, 2003.

### BACKGROUND OF THE INVENTION

1. Field of the Invention

This present invention relates to a semiconductor manufacturing, and more particularly, to a method for preventing the edge peeling defect after an interconnect process.

2. Description of the Prior Art

Interconnect plays an important role in a semiconductor structure. For instance of copper interconnect, particularly for the semiconductor manufacture of deep sub-micron (DSM), by employing Copper interconnect process and the low-K material as the dielectric layer, the RC delay (resistance capacitance time delay) and the electro-migration effect can be reduced.

For example, FIG. 1 depicts a flowchart of a copper interconnect structure in the prior art. Referring to FIG. 1, first of all, a Copper interconnect layer is formed on a wafer, as the step 120. The Copper interconnect layer can be formed by electro-chemical plating (ECP) or other well-known technology. Subsequently, a step is performed for planarizing the surface of the Copper interconnect layer and removing the redundant Copper on the wafer by chemical mechanical polishing (CMP) or the like technology, as the step 140. Next, referring to the step 160, a wafer cleaning and drying step is performed. Afterward the wafer can be sent to the next process as shown in the step 180.

In a metal(Copper) interconnect manufacturing process, a barrier layer, which is consisted of Ta, TaN, or the like materials, is employed for keeping the metal from diffusing into the other elements under the metal interconnect layer. However, because the adhesion of the barrier layer to some structure, such as the bare Si, is not good enough, the peeling of portions of the barrier layer at the wafer edge, even including the structure on the barrier layer at he wafer edge, may happen during the following process. The above-mentioned peeling will cause many defects in the semiconductor manufacture. For example, the yield of the wafer manufacture may be reduced by the above-mentioned peeling. If the peeling is serious, the wafer will become useless and waste. Moreover, the chamber(s) of the semiconductor manufacture will be polluted by the above-mentioned peeling.

Hence, for improving the yield of the semiconductor manufacture and reducing the pollution of the chambers, it is an important object to provide a method for preventing edge peeling defect.

### SUMMARY OF THE INVENTION

In accordance with the present invention, a method for preventing edge peeling defect is provided for preventing the peeling defects by introducing a step for removing the structure or thin film at the wafer edge in an interconnect manufacture, so that the peeling defects in the prior art can be efficiently prevented.

It is another object of this invention to raising the yield of the semiconductor manufacture by performing a step for removing the thin film at the wafer edge and at the wafer backside.

It is still another object of this present invention to decrease the pollution source of the chamber(s) of the semiconductor manufacture by performing a step for removing the thin film at the wafer edge and at the wafer backside after forming an interconnect layer on the wafer, wherein the structure may be peeling in the following process, and thus the pollution chance of the chamber(s) will be lowered by this invention.

In accordance with the above-mentioned objects, the invention provides a method for preventing edge peeling defect. The above-mentioned method can be applied in an interconnect manufacture. According to this prevent invention, after forming a structure comprising an interconnect layer on a wafer, a step is introduced for removing the structure or thin film at the wafer edge, wherein the structure or thin film is not covered by the metal interconnect layer and may be peeling in the following process. The above-mentioned structure or thin film can be removed by the edge bevel removal technology, or the edge polishing technology. Therefore, according to this invention, it is efficiently for preventing the peeling defects in the prior art, and the yield of the semiconductor manufacture can be efficiently improved. Moreover, the pollution, due to the peeling fragment, of the chamber(s) of the semiconductor manufacture can be decreased by the design of this invention.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a flowchart for manufacturing a Copper interconnect according to the prior art;

FIG. 2 is a flowchart of the method for preventing edge peeling defect according to this presented invention;

FIG. 3A is a flowchart of another method for preventing edge peeling defect of this present invention;

FIG. 3B is another flowchart of the method for preventing edge peeling defect according to this present invention;

FIG. 3C is still another flowchart of the method for preventing edge peeling defect according to this invention;

FIG. 4A shows a substrate having a dielectric layer thereon and trenches formed in the dielectric layer; and

FIG. 4B shows a result of planarizing a patterned metal structure to remove a portion of the patterned metal structure and the thin film until the dielectric layer is exposed and removing the thin film at the edge bevel of the substrate and the dielectric layer.

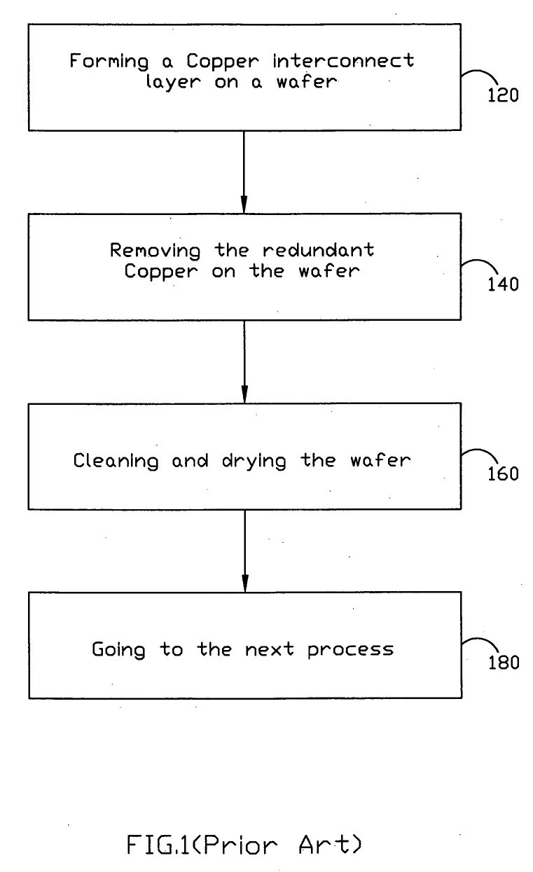

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

One preferred embodiment of this invention is a method for preventing edge peeling defect. In a metal interconnect manufacturing, in order to keeping the metal diffusing into the substrate or other structure under the metal interconnect layer, a thin film is usually formed on the substrate or the structure under the metal interconnect layer to be the barrier layer before forming the metal interconnect layer. The thin film can be formed by deposition, i.e. Physical Vapor Deposition. After the metal interconnect layer is formed, the barrier layer at the edge bevel on the wafer would appear as a thin film because the removal of the part of upper interconnect layer. According to this embodiment, a step for cleaning the edge bevel of the wafer is introduced, and thus the defects caused by the edge peeling in the prior art can be efficiently prevented by the method of this embodiment.

The method of this embodiment at least comprises the steps of forming a barrier layer and forming a mental layer structure on a wafer, and removing the weakly adhesive film at the wafer edge. The step of removing the weakly adhesive film at the wafer edge is employed for removing the thin film at the wafer edge or wafer backside not covered by the metal layer. In one case of this present embodiment, an edge bevel removal (EBR) technology may be employed in the above-mentioned step for removing the weakly adhesive film at the wafer edge. In this case, the weakly adhesive film at the wafer edge or at the wafer backside can be removed by the EBR technology with an acid aqueous.

In another case of this embodiment, the weakly adhesive film at the wafer edge or at the wafer backside can be removed by the edge polishing technology. In this case, a base slurry is employed in the above-mentioned step during removing the weakly adhesive film with the edge polishing technology.

Another preferred embodiment of this present invention is a method for preventing edge peeling defect. According to this embodiment, between the steps of manufacturing the metal interconnect layer and going to the next semiconductor process, a step for removing weakly adhesive film at the edge bevel or at the wafer backside is performed for preventing the peeling defects in the prior art.

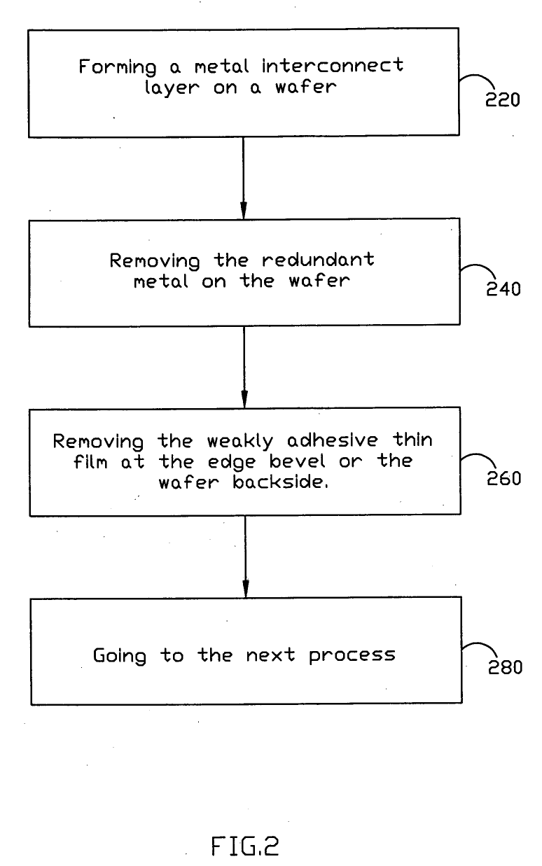

FIG. 2 shows a flowchart of an interconnect manufacture of this embodiment. Referring to FIG. 2, first of all, a metal interconnect layer is formed on a wafer, as the step 220. The metal interconnect layer is consisted of Copper, Aluminum, or other metal materials. The metal interconnect layer may be formed by electrochemical plating (ECP) or other well-known technology. Next, step 240 for planarizing the metal interconnect layer and removing the redundant metal on the wafer is performed with an usual technology, such as chemical mechanical polishing (CMP), edge bevel removal (EBR), or the likes.

Subsequently, as shown in the step 260, the structure or thin film at the wafer edge or at the wafer backside, such as the barrier layer or the upper mental layer structure at the wafer edge, is removed. The above-mentioned structure or thin film at the wafer edge is not covered by the metal interconnect layer and may be peeling in the following processes. In one case of this embodiment, the EBR technology may be employed in the step 260 for removing the structure or thin film. An acid aqueous may be used in the EBR treatment for removing the weakly adhesive structure at the wafer edge or at the wafer backside. One of the formulas of the above-mentioned acid aqueous comprises nitric acid (HNO₃) and hydrofluoric acid (HF). In the mentioned formula, the concentration of HNO₃ is about 5-45%, and the concentration of HF is about 0.1-5%. The EBR treatment can be performed at 20-70 □.

In another case of this embodiment, the barrier layer or other structure at the wafer edge or at the wafer backside can be removed by the edge polishing technology. During the edge polishing treatment, a base slurry may be used for removing the structure. The mentioned base slurry may be a base Silica slurry, and the pH of the slurry is about 7-12. It should be noted that all the descriptions of the treatment of the step 260 and the acid/base solution, such as the formulas, the ratio, and other parameters, are employed for the explanation of the embodiment, and this invention is not limited by the above-mentioned descriptions.

After removing weakly adhesive thin film at the edge bevel or at the wafer backside (as the step 260 in FIG. 2), the next semiconductor process can be performed onto the wafer, as the step 280. In another case of this embodiment, before performing the next semiconductor process, a treatment of wafer cleaning and drying may be employed for removing the residue on the surface of the wafer, not shown in FIG. 2.

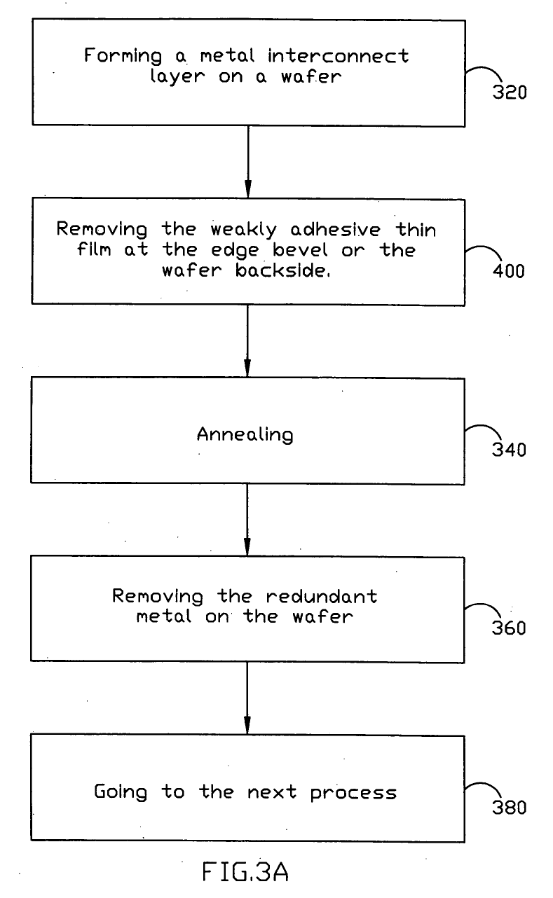

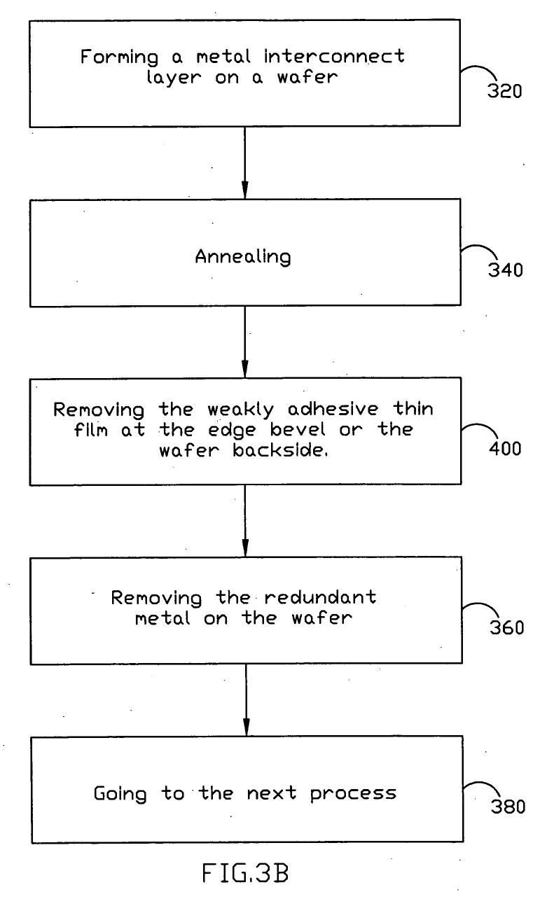

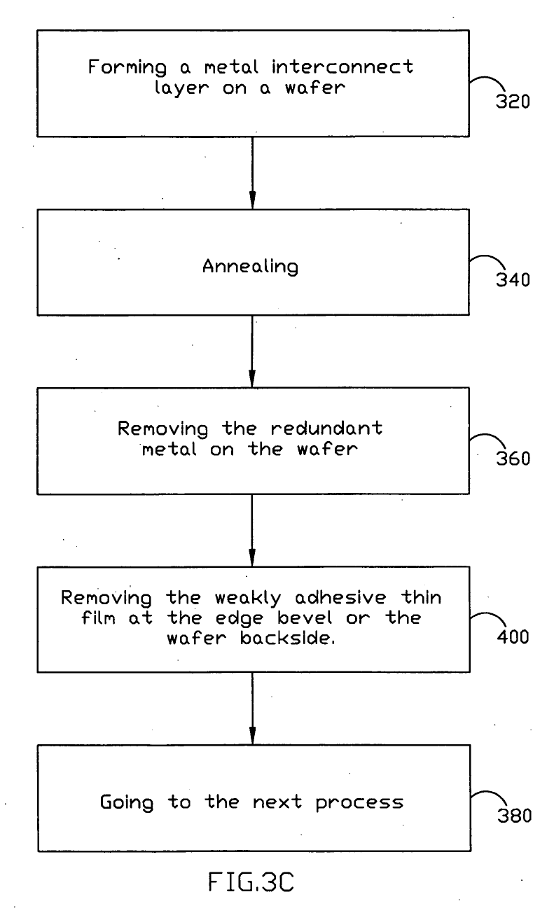

Another preferred embodiment according to this present invention is a method for preventing edge peeling defect. FIG. 3A to 3C respectively depicts three applications of the method for preventing edge peeling defect according to this embodiment. Referred to FIG. 3A, an interconnect manufacturing usually comprises the steps of forming an interconnect layer on a wafer (as the step 320); annealing (as the step 340); planarizing the metal interconnect layer and removing the metal at the edge bevel or at the wafer backside by CMP or other treatment (as the step 360); and going to the next semiconductor process (as the step 380). The metal interconnect layer may be consisted of Copper, Aluminum, or other metal materials, and formed by ECP or other well-known technology.

In order to keeping the metal of the metal interconnect layer from diffusing into other structure under the metal interconnect layer, such as the substrate or the dielectric layer, a conformal barrier layer is formed on the wafer before forming the metal interconnect layer. The barrier layer is consisted of TaN, Ta, TiN, TiW, or the like materials. However, the adhesion of the barrier layer to some semiconductor structure, such as bare Si, is not good enough, and thus many defects caused by the peeling of the redundant barrier layer at the wafer edge or at the wafer backside will happen at the following semiconductor processes.

In order to resolve the above-mentioned peeling defects, a step for removing the weakly adhesive thin film at the edge bevel or at the wafer backside (as the step 400) is performed between the steps of forming the metal interconnect layer (as the step 320) and going to the next semiconductor process (as the step 380) in this embodiment. The above-mentioned step for removing the weakly adhesive thin film at the wafer edge or at the wafer backside is employed for removing the redundant barrier layer or other unwanted structure not covered by the metal interconnect layer (the redundant barrier layer and other unwanted structure are not patterned), wherein the above-mentioned redundant barrier layer or the unwanted structure might be peeling in the following processes. Thus, the peeling defects in the prior art can be efficiently prevented by the design of this embodiment.

Referring to FIG. 3A, showing a flowchart of one case of the method for preventing edge defect according to this embodiment, the step for removing the weakly adhesive thin film at the edge bevel or at the wafer backside (as the step 400) can be performed before the annealing step (as the step 340). In the above-mentioned step 400, the EBR treatment may be employed for removing the redundant barrier layer or the unwanted structure at the wafer edge or at the wafer backside, wherein the barrier layer or the unwanted structure or thin film is not covered by the metal interconnect layer. The EBR treatment may be performed with an acid solution. In one case of this embodiment, the acid solution is an aqueous comprising HNO₃ (about 5-45%) and HF (about 0.1-5%).

Instead of the EBR technology, the edge polishing technology can be employed in the above-mentioned step for removing the weakly adhesive thin film at the edge bevel or at the wafer backside (as the step 400) to remove the redundant barrier layer or unwanted structure at the wafer edge or at the wafer backside. In the edge polishing treatment, a base slurry may be employed for removing the weakly adhesive thin film at the edge bevel or at the wafer backside. In one case of this embodiment, the base slurry may be a Silica slurry, and the pH of the slurry is about 7-12.

In another case of this embodiment, referring to FIG. 3B, the above-mentioned step for removing the weakly adhesive thin film at the edge bevel or at the wafer backside (the step 400) is performed between the step of annealing (as the step 340) and the step for removing the metal at the edge bevel or at the wafer backside (as the step 360). In this case, the unwanted structure or thin film can be removed by employing the EBR treatment with the acid solution, or by employing the edge polishing treatment with the base slurry. The above-mentioned unwanted structure is the incompletely patterned part of mental interconnect layer at the wafer edge or at the wafer backside, and is not covered by the metal interconnect layer. The above-mentioned unwanted structure may be peeling in the following process.

In still another case of this embodiment, referring to FIG. 3C, the above-mentioned step 400 of removing the weakly adhesive thin film at the edge bevel or at the wafer backside can be performed after the step for removing the metal at the edge bevel or at the wafer backside (as the step 360). In this case, the unwanted structure or thin film also can be removed by the EBR treatment with the acid solution, or by the edge polishing with the base slurry.

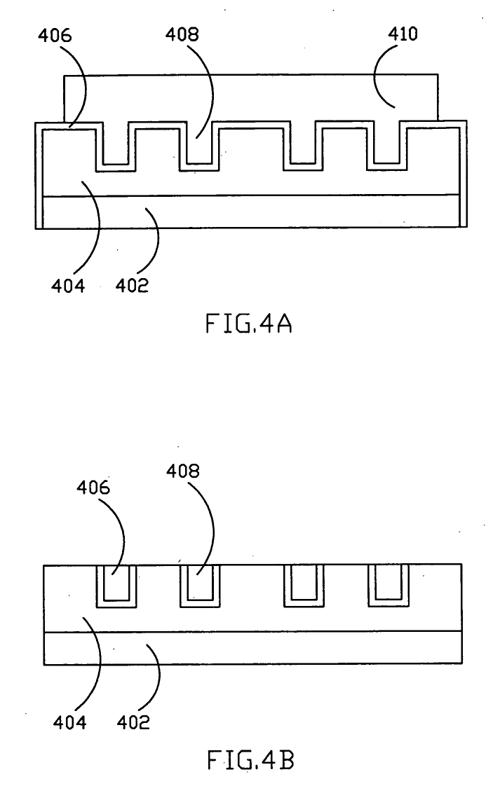

FIG. 4A shows a substrate 402 having a dielectric layer 404 thereon, wherein trenches 408 are formed in the dielectric layer 404. The substrate 402 comprises a silicon substrate having integrated circuit device therein and the dielectric layer 404 can be any suitable dielectric layer used in the integrated circuit process. The dielectric layer 404 and the trench 408 can be formed by any suitable process in the art. Then a thin film 406 is formed on the top surface of the dielectric layer 404 and at the edge bevel of the substrate 402 and the dielectric layer 404. The thin film 406 can be any suitable layer such as a barrier layer for preventing metal diffusion used in the integrated circuit process formed by any suitable process in the art. Next a patterned metal structure 410 comprising a metal interconnect layer is formed on the top surface of the thin film 406, wherein the thin film 406 at the edge bevel of the substrate 402 and the dielectric layer 404 are not covered by the patterned metal structure 410. Then the patterned metal structure 410 is planarized and a portion of the patterned metal structure and the thin film 406 are removed until the dielectric layer 404 is exposed as shown in FIG. 4B. The thin film 406 at the edge bevel of the substrate 402 and the dielectric layer 404 is then removed as shown in FIG. 4B. It is noted that the thin film 406 at the edge bevel of the substrate 402 and the dielectric layer 404 can be removed before the patterned metal structure 410 is planarized to expose the dielectric layer 404.

It should be noted that all the above-mentioned description about the step for removing the weakly adhesive thin film at the edge bevel or at the wafer backside, including the parameters of the acid and the base solutions, such as the formulas, the ratio, and the others, are employed for explanation this embodiment, and this invention should not be limited to the descriptions.

In the semiconductor manufacture in the prior art, in order to keeping the metal of the metal interconnect layer from diffusing into other structure under the metal interconnect layer, a barrier layer is usually formed on the wafer before forming the metal interconnect layer. After forming the metal interconnect layer, portions of the barrier layer at the wafer edge will not be covered by the metal interconnect layer, and be exposed. Because the adhesion of the barrier layer to some semiconductor structure, such as the bare Si, is not good enough, the exposed barrier layer at the wafer edge will be possibly peeling in the next processes following the interconnect manufacture. The above-mentioned peeling will cause many defects, for example, the decreasing of the yield of the wafer. Particularly, if the peeling is serious, the wafer will become useless. Moreover, the chamber(s) of the semiconductor manufacture will be polluted by the fragments of the above-mentioned peeling. It should be noted that there is still no suitable way for resolving the peeling defects in the prior art, particularly in the Copper interconnect manufacture.

However, according to this present invention, the above-mentioned peeling defects can be efficiently prevented by introducing a step for removing the weakly adhesive thin film at the edge bevel or at the wafer backside after forming the metal interconnect layer. That is, the above-mentioned step for removing the weakly adhesive thin film at the edge bevel or at the wafer backside is performed between the step of forming the metal interconnect layer and the step of going to the next process. The above-mentioned step of this invention is employed for removing the unwanted structure at the wafer edge or at the wafer backside, wherein the structure or thin film may be peeling in the following processes. The above-mentioned structure or film is not covered by the metal interconnect layer and removed by the design of this invention. Thus, the defects caused by the above-mentioned peeling, such as the decreasing of the yield, the pollution of the chamber(s), and the likes, can be efficiently resolved. Therefore, according to the design of this invention, the yield can be efficiently raised, and the pollution chance of the chamber(s) can be lowered.

According to the preferred embodiments, this invention discloses a method for preventing edge peeling defect. The above-mentioned method can applied in an interconnect manufacture. In this present invention, the method for preventing edge peeling defect at least comprises the steps of forming a structure comprising a metal interconnect layer on a wafer, and a step for removing the weakly adhesive thin film at the edge bevel or at the wafer backside. The unwanted structure, comprising the barrier layer at the wafer edge, is not covered by the metal interconnect layer, and may be peeling in the following processes. In the above-mentioned step of this invention, the unwanted structure or thin film can be removed by an EBR treatment, or by an edge polishing treatment. Therefore, this present invention can efficiently prevent the defects caused by the peeling of the unwanted structure or thin film in the prior art. According to the design of this invention, the yield of the semiconductor manufacture can be efficiently raised. Preferably, the chamber(s) of the semiconductor manufacture can be kept from the pollution of the peeling fragments in the prior art, and the pollution chance of the chamber(s) can be decreased.

Although specific embodiments have been illustrated and described, it will be obvious to those skilled in the art that various modifications may be made without departing from what is intended to be limited solely by the appended claims.

What is claimed is:

1. A method for preventing edge peeling defect, comprising:
providing a substrate;
forming a dielectric layer on said substrate, wherein at least a trench formed in said dielectric layer;
forming a thin film on the top surface of said dielectric layer and at the edge bevel of said substrate and said dielectric layer;
forming a patterned metal structure on the top surface of said thin film, wherein said thin film at the edge bevel of said substrate and said dielectric layer are not covered by said patterned metal structure;
planarizing said patterned metal structure and removing a portion of said patterned metal structure and said thin film until said dielectric layer is exposed; and
removing said thin film at the edge bevel of said substrate and said dielectric layer.

2. The method according to claim 1, wherein said thin film comprises a barrier layer for preventing metal diffusion.

3. The method according to claim 1, wherein the material of said barrier layer is chosen from the group comprising the following: Ta, TaN, TiN and TiW.

4. The method according to claim 1, wherein said thin film is formed by physical vapor deposition.

5. The method according to claim 1, wherein said patterned metal structure comprises an interconnect layer.

6. The method according to claim 5, wherein said patterned metal structure is chosen from the group comprising the following: copper and aluminum.

7. The method according to claim 1, wherein the step for removing said thin film at the edge bevel of said substrate and said dielectric layer comprises etching and chemical mechanical polishing.

8. The method according to claim 1, wherein said step for removing said thin film at the edge bevel of said substrate and said dielectric layer is at the backside of said wafer.

9. The method according to claim 1, wherein said step for removing said thin film at the edge bevel of said substrate and said dielectric layer employs an edge bevel removal technology.

10. The method according to claim 9, wherein said step for removing said thin film at the edge bevel of said substrate and said dielectric layer employs an acid solution.

11. The method according to claim 9, wherein said step for removing said thin film at the edge bevel of said substrate and said dielectric layer employs an edge polishing technology.

12. The method according to claim 11, wherein said step for removing said thin film at the edge bevel of said substrate and said dielectric layer employs a base slurry.

13. The method according to claim 11, wherein said step for removing s said thin film at the edge bevel of said substrate and said dielectric layer comprises a treatment of wafer drying.

14. A method for preventing edge peeling defect, comprising:
providing a substrate;
forming a dielectric layer on said substrate, wherein at least a trench formed in said dielectric layer;
forming a barrier layer on the top surface of said dielectric layer and at the edge bevel of said substrate and said dielectric layer;
forming a metal interconnect layer onto said barrier layer, wherein said barrier layer at the edge bevel of said substrate and said dielectric layer are not covered by said metal interconnect layer;
removing said barrier layer not covered by said metal interconnect layer; and
planarizing said metal interconnect layer and removing a portion of said metal layer and said barrier layer until said dielectric layer is exposed.

15. The method according to claim 14, wherein the material of said barrier layer is Ta.

16. The method according to claim 14, wherein the material of said barrier layer is TaN.

17. The method according to claim 14, wherein said metal interconnect layer is a Copper interconnect layer.

18. The method according to claim 14, wherein said metal interconnect comprises said thin film exposed at the wafer backside.

19. The method according to claim 14, wherein said step for removing said barrier layer not covered by said metal interconnect layer comprises removing said thin film at the wafer backside.

20. The method according to claim 14, wherein said step for removing said barrier layer not covered by said metal interconnect layer comprises removing the incompletely patterned part of said metal interconnect layer upper said barrier layer.

21. The method according to claim 14, wherein said step for removing said barrier layer not covered by said metal interconnect layer comprises an edge bevel removal treatment.

22. The method according to claim 21, wherein said step for removing said barrier layer not covered by said metal interconnect layer employs an acid solution.

23. The method according to claim 22, wherein said step for removing said barrier layer not covered by said metal interconnect layer employs an acid solution comprising nitric acid and hydrofluoric acid.

24. The method according to claim 14, wherein said step for removing said barrier layer not covered by said metal interconnect layer comprises an edge polishing treatment.

25. The method according to claim 24, wherein said step for removing said barrier layer not covered by said metal interconnect layer employs a base slurry.

26. The method according to claim 25, wherein the pH of said base slurry is pH 7.about.12.

27. The method according to claim 14, wherein said step for planarizing the metal interconnect layer and removing a portion of said metal layer on the wafer comprises etching for planarizing and chemical mechanical polishing.

28. The method according to claim 14 further comprising a step of annealing said substrate after removing said barrier layer not covered by said metal interconnect layer.

29. The method according to claim 14 further comprising a step of annealing said substrate after the step of forming a metal interconnect layer onto said barrier layer.
